(19) United States
(12) Patent Application Publication
(10) Pub. No.: US 2026/0088768 A1
(43) Pub. Date: Mar. 26, 2026

(54) ENVELOPE-TRACKING AMPLIFIER WITH INPUT SIGNAL VARIATION FOR CONSTANT COMPRESSION OPERATION

(71) Applicant: QUALCOMM Incorporated, San Diego, CA (US)

(72) Inventors: Hakan INANOGLU, Acton, MA (US); Leon METREAUD, Pepperell, MA (US); Nicholas SHUTE, Impington (GB)

(21) Appl. No.: 18/893,807

(22) Filed: Sep. 23, 2024

(51) Int. Cl. H03F 1/02; H03F 3/24

(52) U.S. Cl. CPC H03F 1/0233; H03F 3/245; H03F 2200/105; H03F 2200/451

(57) ABSTRACT

A transmitter is provided that determines a compression of an envelope-tracking amplifier using a function of the amplifier's power supply voltage, input signal voltage, and output signal voltage. An input signal adjustment circuit adjusts the input signal to the envelope-tracking amplifier responsive to a difference between the compression and a desired fixed value for the compression.

### TECHNICAL FIELD

The present application relates generally to amplifiers, and more specifically, to envelope-tracking amplifiers with input signal variation for constant compression operation.

### BACKGROUND

Modern communication protocols such as 5G use orthogonal frequency division multiplexing (OFDM) modulation techniques for various reasons including improved performance over severe channel conditions. But the use of OFDM complicates the transmitter's power amplifier biasing due to OFDM's relatively high peak to average power. Should the power amplifier use a constant supply voltage having an amplitude sufficient for linear operation at the peak signal power, the power amplifier efficiency then suffers since the majority of the signaling occurs at the average power level. Conversely, should the power amplifier use a constant supply voltage biased for the average signal power, then linearity is degraded at the peak signal power.

Envelope-tracking power amplifiers solve this dilemma because the power supply voltage tracks the signal envelope. The envelope tracking ensures that the power amplifier operates in compression and thus with high efficiency. But maintaining the same amount of compression is challenging.

### SUMMARY

In accordance with an aspect of the disclosure, a transmitter is provided that includes: an envelope-tracking amplifier configured to amplify an input signal having an input voltage into an output signal having an output voltage; and an input signal adjustment circuit configured to adjust the input voltage responsive to a current power supply voltage to the envelope-tracking amplifier, the input voltage, and the output voltage to maintain a fixed amount of compression for the envelope-tracking amplifier.

In accordance with another aspect of the disclosure, a method of maintaining an amplifier compression is provided that includes: forming an envelope-tracking power supply voltage based upon an envelope of an input signal; amplifying the input signal in an amplifier powered by an envelope-tracking power supply voltage to form an output signal; mapping the envelope-tracking power supply voltage into an input voltage scaling factor and into an output voltage scaling factor; multiplying a voltage of the input signal by the input voltage scaling factor to form a scaled input voltage; multiplying a voltage of the output voltage by the output voltage scaling factor to form a scaled output voltage; determining a current compression of the amplifier responsive to a function of the scaled output voltage and the scaled input voltage; and adjusting the input signal to maintain a fixed amount of compression for the amplifier based upon a difference between the current compression and fixed amount of compression.

Finally, in accordance with yet another aspect of the disclosure, a transmitter is provided that includes: an envelope-tracking amplifier; means for calculating a compression for the envelope-tracking amplifier from a power supply voltage to the envelope-tracking amplifier, an input signal voltage to the envelope-tracking amplifier, and output signal voltage from the envelope-tracking amplifier; and means for adjusting the input signal voltage to the envelope-tracking amplifier based upon a difference between the compression and a desired fixed value for the compression.

These and other advantageous features may be better appreciated through the following detailed description.

### BRIEF DESCRIPTION OF THE DRAWINGS

FIG. 1 illustrates a plurality of AMAM curves for various power supply voltages and temperatures.

FIG. 2 illustrates some example scaling factors for the input and output voltages to an envelope-tracking power amplifier to achieve a fixed amount of compression in accordance with an aspect of the disclosure.

FIG. 3 illustrates an example transmitter including an envelope-tracking power amplifier with input power adjustment to achieve a fixed amount of compression in accordance with an aspect of the disclosure.

FIG. 4 illustrates an example wireless device including an envelope-tracking power amplifier with input power adjustment to achieve a fixed amount of compression in accordance with an aspect of the disclosure.

FIG. 5 is a flowchart for an example method of adjusting the input signal power to an envelope-tracking power amplifier to achieve a fixed amount of compression in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

As the power supply voltage varies, an envelope-tracking power amplifier's amplitude-modulation to amplitude-modulation (AMAM) and amplitude-modulation to phase-modulation (AMPM) behavior will also vary. These variations can cause the power amplifier to undesirably produce a non-linear amplitude response. Digital pre-distortion may account for this non-linearity such that the overall behavior of the resulting transmitter is linear. But as the envelope-tracking power supply voltage changes, the gain of an envelope-tracking power amplifier may also vary. A fixed digital amount of digital pre-distortion may have produced a desired degree of linearity with the envelope-tracking power amplifier operating with a default amount of gain but as the gain varies the transmitter may drift into non-linear behavior.

The efficiency of an envelope-tracking power amplifier is advantageous for the large peak-to-average power ratio of OFDM signaling but this efficiency requires the envelope-tracking power amplifier to always operate in compression. The compression produces non-linearity that may be corrected through digital pre-distortion. A fixed amount of compression may thus operate with a fixed amount of digital pre-distortion such that a desired compromise between efficiency and linearity is achieved. But the compression varies as the envelope-tracking power amplifier's gain varies due to temperature and frequency changes. Various calibration approaches have been used for power amplifiers with envelope tracking to attempt to maintain a constant level of compression across the expected operating temperature and frequency ranges. But the AMAM (or AMPM) behavior as the power supply voltage tracks the input signal envelope is quite complex and forces existing calibration techniques to either undesirably compromise or be excessively complex to implement.

For a fixed amount of digital pre-distortion, the input signal power (Pin) to an envelope-tracking power amplifier may be adjusted to provide a fixed amount of compression despite the changes in the power supply voltage. But adjusting the input signal power is difficult in conjunction with envelope tracking because the degree or level of compression cannot be measured directly. An envelope-tracking power amplifier is disclosed herein in which the input signal power or voltage is adjusted to provide a fixed amount compression without the need for compromise or excessive complication. This advantageous adaptation of the input signal to the envelope-tracking power amplifier takes advantage of the following discovery: a power amplifier's AMxM curves (where x is either A for AMAM or P for AMPM) that result from plotting the AMxM behavior as power supply voltage is changed will tend to be scaled versions. In particular, the x axis for these AMxM curves may be the input signal voltage or input signal power whereas the y axis may be either the output signal voltage, the output power, or the amplifier gain. Regardless of the particular input variable versus the particular output variable for the AMxM curves, the resulting curves will be substantially scaled versions of each other. Some example AMAM curves will now be discussed in more detail.

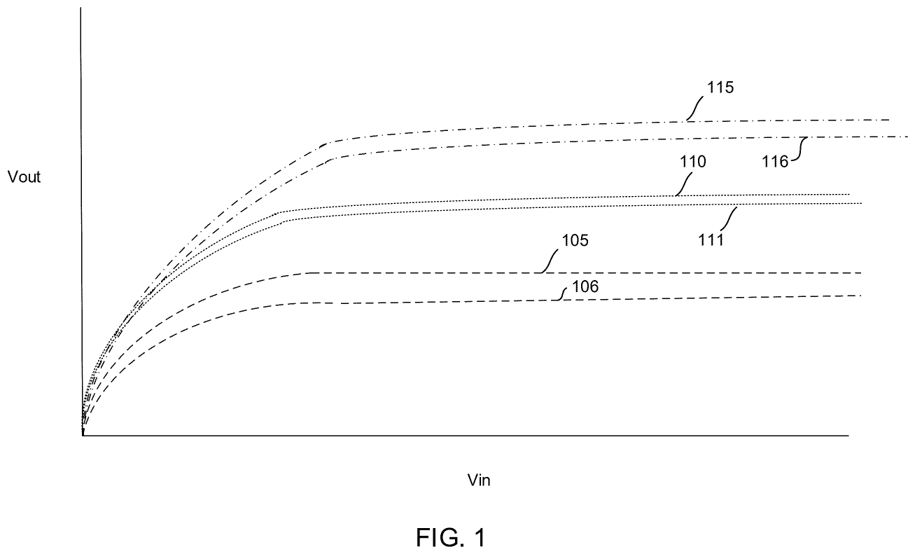

For example, FIG. 1 illustrates a plurality of AMAM curves with each AMAM curve being a function of the input voltage (Vin) versus the output voltage (Vout) of the power amplifier. The frequency is not shown but it may be assumed to be midband in these examples. In FIG. 1, an AMAM curve 105 corresponds to the use of a first power supply voltage (Vcc1) with the power amplifier at a first temperature (e.g., room temperature). An AMAM curve 110 corresponds to the use of a second power supply voltage (Vcc2) that is greater than the second power supply voltage with the power amplifier at the first temperature. In addition, an AMAM curve 115 corresponds to the use of a third power supply voltage (Vcc3) that is greater than the second power supply voltage with the power amplifier at the first temperature. It may be seen that curves 105, 110, and 115 are all scaled versions of each other. In other words, through an appropriate scaling of the input voltage and the output voltage, each AMAM curve may be collapsed onto (made to be substantially equal to) another one of the AMAM curves.

Curves 105, 110, and 115 show the effect of changing the power supply voltage at a fixed temperature and frequency. But an analogous scaling of the AMAM curves results from changing the temperature and/or the frequency. For example, an AMAM curve 106 results from the use of the first power supply voltage Vcc1 with the power amplifier at a second temperature that is greater than the first temperature. Similarly, an AMAM curve 111 results from the use of the second power supply voltage Vcc2 with the power amplifier at the second temperature. Finally, an AMAM curve 116 an AMAM curve 106 results from the use of the third power supply voltage Vcc3 with the power amplifier at the second temperature. Note that the AMAM curves 106, 111, and 116 are not only scaled versions of each other but also of the AMAM curves 105, 110, and 115. However, the change in the gain (the ratio of Vout/Vin) from room temperature behavior to the lowest-expected temperature or to the highest-expected temperature may be as little as +/−0.25 dB. An analogous relatively small change in gain may occur as the frequency changes from a mid-band frequency to the highest or lowest frequency of the operating frequency band. It may thus be seen that an AMxM curve for room temperature and a mid-band frequency for a given power supply voltage may sufficiently model the AMxM behavior for all the expected temperature and frequency variations at that power supply voltage. The AMxM curves at the mid-band frequency and room temperature (e.g., curves 105, 110, and 115) may thus be collapsed onto a single reference curve. The resulting reference curve may then be used to determine the compression for the envelope-tracking power amplifier as will be further discussed herein.

The power supply voltage will vary from a minimum value to a maximum value as the power supply voltage tracks the input signal envelope. The reference curve may thus correspond to a mid-range power supply voltage in this range, but it will be appreciated that the selection of the reference curve in general is arbitrary. In FIG. 1, the AMAM curve 110 may thus be selected as the reference curve. The remaining AMAM curves for the same mid-range temperature and frequency may be collapsed into the reference curve 110 through a corresponding scaling of the input voltage and the output voltage. Since the AMAM curve 110 is the reference curve, its input voltage scaling factor is unity. Similarly, the output voltage scaling factor for the AMAM curve 110 is unity. But the remaining AMAM curves will have input voltage and output voltage scaling factors that are either greater than or less than unity depending upon the relationship of the curve to the reference curve 110. The advantageous result is that the calibration for the envelope-tracking power amplifier's temperature and the input signal frequency may be absorbed into the scaling factors for a given power supply voltage.

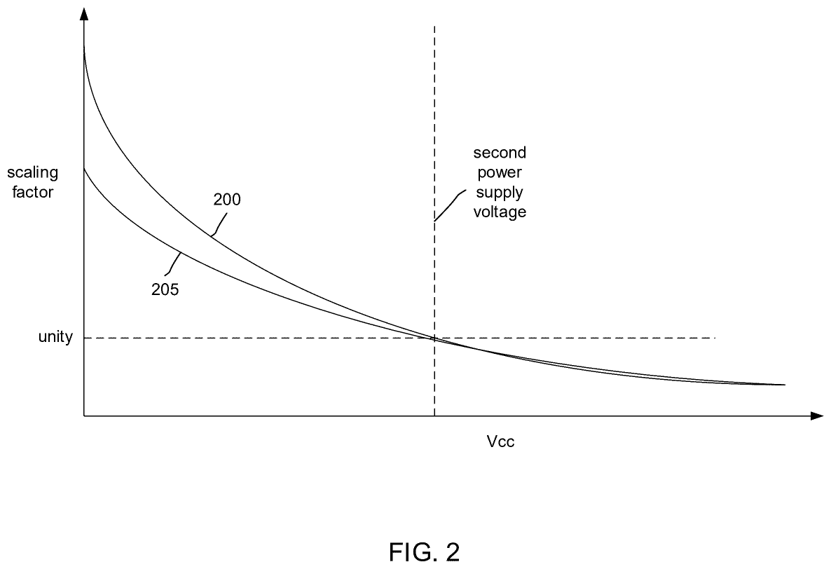

For example, a scaling factor 200 for the input voltage and a scaling factor 205 for the output voltage are plotted in FIG. 2 as a function of the power supply voltage (Vcc) as derived from the AMAM curves 105, 110, and 115 of FIG. 1 with the AMAM curve 110 being the reference curve. Additional AMAM curves for other power supply voltages are not shown but are used to completely sample the expected power supply voltage range. When the power supply voltage Vcc increases to equal the level Vcc2 used to power the power amplifier for the AMAM curve 110, the scaling factors 200 and 205 are unity since the AMAM curve 110 is the reference curve. As the power supply voltage Vcc increases above the level Vcc2, the scaling factors 200 and 205 drop below unity. For example, it would take sub-unity scaling factors to scale the AMAM curve 115 collapse onto the reference AMAM curve 110. Conversely, as the power supply voltage Vcc drops below the level Vcc2, the scaling factors 200 and 205 increase above unity. For example, it would take scaling factors greater than one to scale the AMAM curve 105 to collapse onto the reference AMAM curve 110.

The scaling factors 200 and 205 may be incorporated into a lookup table (LUT) within a transmitter including an envelope tracking power amplifier that maps the power supply voltage level to the input voltage and output voltage scaling factors.

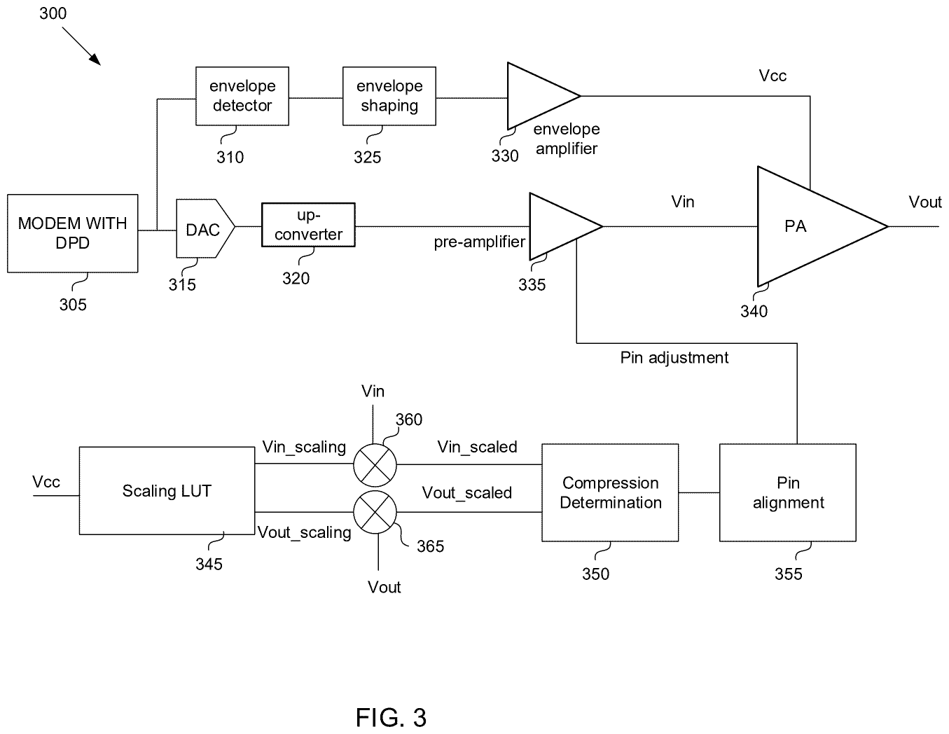

An example transmitter 300 is shown in FIG. 3. A modem 305 generates a digital baseband input signal that it digitally pre-distorts (DPD) into a digitally-predistorted digital baseband input signal. As part of the envelope tracking for an envelope-tracking power amplifier 340, an envelope detector 310 detects the envelope of the digitally-predistorted baseband digital input signal. An envelope shaper 325 shapes the envelope to form a shaped envelope signal that is amplified by an envelope amplifier 330 to form the envelope-tracking power supply voltage Vcc for the envelope-tracking power amplifier 340.

A digital-to-analog converter (DAC) 315 converts the digitally-predistorted digital baseband input signal into an analog baseband input signal that is upconverted in frequency by an up-converter 320 to form a radio frequency (RF) input signal. A pre-amplifier 335 (for example, a driver amplifier or a pre-driver amplifier in series with a driver amplifier) amplifies the RF input signal to form an amplified RF input signal having an input voltage signal (Vin) to the envelope-tracking power amplifier 340. The envelope-tracking power amplifier 340 amplifies the amplified RF input signal to form an RF output signal having an output voltage (Vout). To align the input signal power from the pre-amplifier 335 so that the envelope-tracking power amplifier 340 operates in the desired constant degree of compression, a scaling look-up table (LUT) 345 maps the power supply voltage Vcc to an input voltage scaling factor and an output voltage scaling factor. These scaling factors are generated as described with respect to FIG. 2 and stored in the LUT 345 for various values of the power supply voltage. Depending upon the current power supply voltage Vcc for the power amplifier 340, the LUT 345 provides an input voltage scaling factor Vin_scaling and an output voltage scaling factor Vout_scaling. A multiplier 360 multiplies the input voltage Vin with the input voltage scaling factor Vin_scaling to form a scaled input voltage Vin_scaled. Similarly, a multiplier 365 multiplies the output voltage Vout with the output voltage scaling factor Vout_scaling to form a scaled output voltage Vout_scaled. A compression determination 350 may then be performed by using determining the compression from the reference curve. For example, the reference curve may be converted into a gain plot as a function of the input signal power. For lower levels of the input signal power, the gain is constant such as at a peak level but will drop as the input signal power increases. The amount of drop from the peak gain is the power amplifier compression. The scaled input and output voltages may thus be mapped into the current compression of the envelope-tracking power amplifier 340. Depending upon the desired fixed amount of compression, the current compression may need to be increased or decreased. The input signal power is then adjusted accordingly by the pre-amplifier 335. Note the remarkable advantages of the resulting input power (Pin) adjustment in that no complex calibration is required yet the power amplifier 340 is kept in a fixed amount compression despite temperature and frequency variations. As a result, the desired compromise between linearity and efficiency for the power amplifier 340 is achieved. Moreover, a fixed amount of digital pre-distortion may be used to substantially correct any non-linearity that result from the fixed amount of compression.

Referring again to FIG. 1, it was observed that a room-temperature and mid-range frequency AMxM curve such as the curves 105, 110, and 115 sufficiently modeled the AMxM behavior for a given power supply voltage. But if it is desired that the temperature and frequency variations be accounted for, an additional scaling may be used. This scaling again uses the similarity in shapes for the curves at a fixed power supply voltage despite the frequency and temperature variations. For example, through a first input voltage and output voltage scaling, the various AMxM curves corresponding to a given power supply voltage may be collapsed (made to substantially equal to) a reference one of the curves. The frequency and temperature variations of the power amplifier behavior may thus be characterized by the reference curve through corresponding scaling factors applied to the input voltage and output voltage. For example, suppose that the AMAM curve 105 is the reference curve for the power amplifier behavior when the power amplifier is powered by the power supply voltage Vcc1. Similarly, the AMAM curve 110 may be the reference curve for the power amplifier behavior when the power amplifier is powered by the power supply voltage Vcc2. In the same fashion, the AMAM curve 115 may be the reference curve for the power amplifier behavior when the power amplifier is powered by the power supply voltage Vcc3. More generally, the various AMxM curves for a given power supply voltage as the temperature and frequency are varied may be collapsed into a single reference curve. There may thus be a reference curve for each of a plurality of power supply voltage values. These reference curves for the various power supply voltages may then be collapsed onto what may be denoted as a main reference curve through the scaling factors discussed with regard to FIG. 2. The power supply voltage may thus be mapped through LUT 345 to a first set of input and output voltage scaling factors and then through a second LUT (not illustrated) to one of unscaled AMxM curves for the various temperature and frequency variations. However, it will be assumed in the remaining discussion herein that the frequency and temperature variations in the AMxM behavior are relatively insignificant as compared to effect of the power supply voltage.

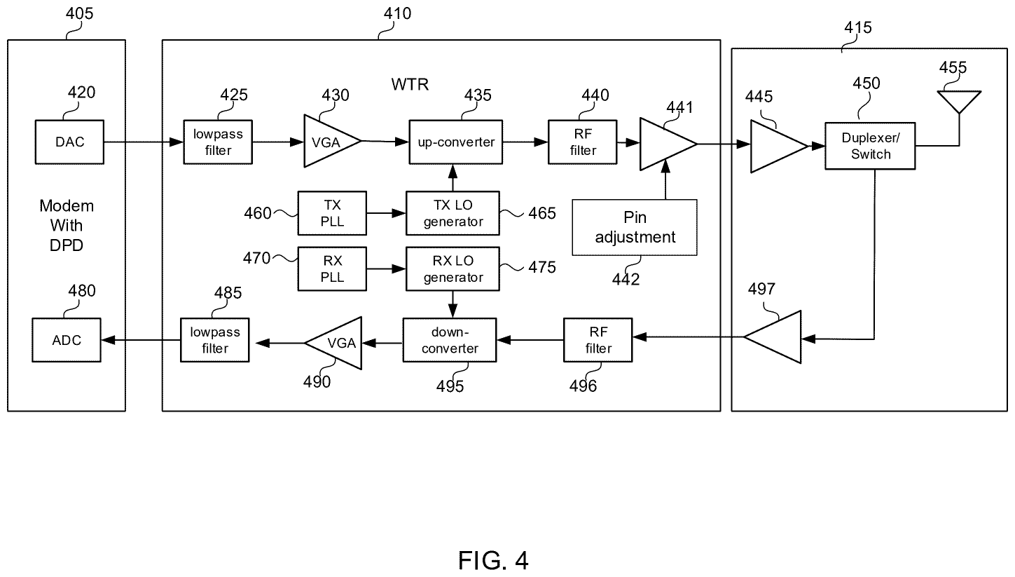

An envelope-tracking power amplifier in which its input signal is adjusted so that a fixed amount compression is achieved as disclosed herein may be advantageously incorporated into any suitable transceiver within a wireless communication device. An example wireless communication device 400 is shown in FIG. 4. A modem 405 (which may also be denoted as a baseband processor) generates a pre-distorted digital baseband signal that is converted into a baseband analog input signal by an at least one digital-to-analog converter (DAC) 420. A wireless transceiver integrated circuit (WTR) 410 includes a lowpass filter 425 for filtering the analog baseband signal to provide a filtered analog signal to a variable gain amplifier (VGA) 430. An up-converter 435 (such as one or more mixers) up converts an amplified analog baseband signal from the VGA 430 in frequency to produce an RF input signal. For example, the up-converter 435 may mix the amplified analog signal with a local oscillator (LO) signal from a transmit (TX) LO generator 435. An oscillator such as a TX phase-locked loop (PLL) 430 clocks the TX LO generator 465 for the generation of the TX LO signal. An RF filter 440 filters the RF signal from the up-converter to produce an RF input signal that is amplified by a driver amplifier 441.

A front-end module 415 includes an envelope-tracking power amplifier 445 for amplifying an RF input signal from the driver amplifier 441. It will be appreciated that additional stages of amplification of the RF input signal prior to the power amplifier 445 such as a pre-driver amplifier (not illustrated) may also be used in alternative implementations. An amplified RF output signal from the power amplifier 445 passes through an antenna switch module (duplexer/switch) 450 to an antenna(s) 455 for wireless transmission. To maintain a constant compression for the power amplifier 445, a power-in (Pin) adjustment circuit 442 adjusts the input signal power to the power amplifier 445 by varying the gain from the driver amplifier 441. Referring again to FIG. 3, the Pin adjustment circuit 442 may be formed such as through the use of the scaling LUT 345, the multipliers 360 and 365, the compression determination 350, and the Pin alignment 355.

During a receive mode, a received RF signal from the antenna(s) 455 passes through the antenna switch module 450 to a low-noise amplifier 497. The WTR 410 also includes an RF filter 496 for filtering an amplified RF received signal from the LNA 497. A down-converter 495 (such as one or more mixers) down converts the filtered RF signal from the RF filter 496 in frequency to produce a down-converted analog signal. For example, the down-converter 495 may mix the filtered RF signal with an LO signal from a receive (RX) LO generator 475. An oscillator such as an RX phase-locked loop (PLL) 470 clocks the RX LO generator 475 for the generation of the RX LO signal. Another VGA 490 amplifies the down-converted analog signal from the down-converter 495 to drive a lowpass filter 485 that provides a filtered analog baseband signal to an analog-to-digital (ADC) 480 in the modem 405. The analog-to-digital converter (ADC) 480 recovers the digital baseband signal for further processing by the modem 405. It will be appreciated that the WTR 410 is merely exemplary and that other transceiver architectures may be used in conjunction with the input power alignment for an envelope-tracking power amplifier as disclosed herein.

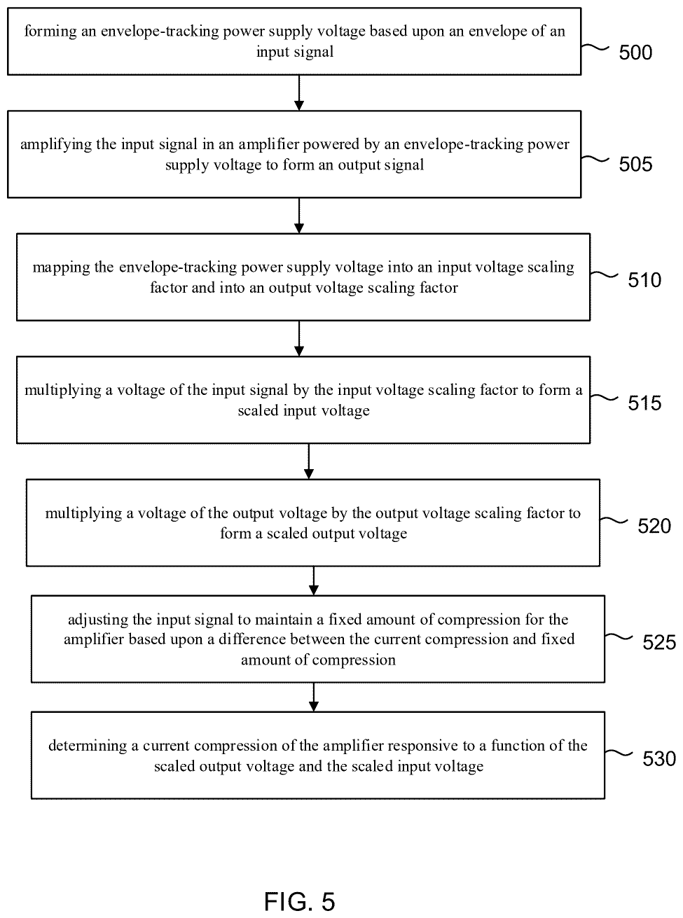

A flowchart for an example method of maintaining an amplifier compression will now be discussed with reference to FIG. 5. The method includes an act 500 of forming an envelope-tracking power supply voltage based upon an envelope of an input signal. The formation of the power supply voltage Vcc as discussed with respect to the transmitter 300 is an example of act 500. The method further includes an act 505 of amplifying the input signal in an amplifier powered by an envelope-tracking power supply voltage to form an output signal. The amplification by the power amplifier 340 is an example of act 505. The method also includes an act 510 of mapping the envelope-tracking power supply voltage into an input voltage scaling factor and into an output voltage scaling factor. The mapping by the scaling LUT 345 is an example of act 510. In addition, the method includes an act 515 of multiplying a voltage of the input signal by the input voltage scaling factor to form a scaled input voltage and also an act 520 of multiplying a voltage of the output voltage by the output voltage scaling factor to form a scaled output voltage. The multiplication by multipliers 360 and 365 is example of acts 515 and 520, respectively. The method further includes an act 525 of determining a current compression of the amplifier responsive to a function of the scaled output voltage and the scaled input voltage. The compression determination 350 is an example of act 525. Finally, the method includes an act 530 of adjusting the input signal to maintain a fixed amount of compression for the amplifier based upon a difference between the current compression and fixed amount of compression. The adjustment of the gain of the pre-amplifier 335 is an example of the act 530.

Some example implementations will now be summarized through the following numbered clauses:

Clause 1. A transmitter, comprising:
an envelope-tracking amplifier configured to amplify an input signal having an input voltage into an output signal having an output voltage; and
an input signal adjustment circuit configured to adjust the input voltage responsive to a current power supply voltage to the envelope-tracking amplifier, the input voltage, and the output voltage to maintain a fixed amount of compression for the envelope-tracking amplifier.

Clause 2. The transmitter of clause 1, wherein the input signal adjustment circuit includes a look-up table for providing an input voltage scaling factor and an output voltage scaling factor responsive to the current power supply voltage.

Clause 3. The transmitter of clause 2, wherein the input signal adjustment circuit further includes a first multiplier for multiplying the input voltage with the input voltage scaling factor to provide a scaled input voltage and includes a second multiplexer for multiplying the output voltage with the output voltage scaling factor to provide a scaled output voltage, and wherein the input signal adjustment circuit is further configured to map the scaled input voltage and the scaled output voltage to determine a current compression for the envelope-tracking amplifier.

Clause 4. The transmitter of clause 3, wherein the input signal adjustment circuit is further configured to map the scaled input voltage and the scaled output voltage into a current gain for the envelope-tracking amplifier, and to determine the current compression as a difference between a maximum gain for the envelope-tracking amplifier and the current gain.

Clause 5. The transmitter of any of clauses 1-4, further comprising:
a pre-amplifier configured to amplify a radio frequency signal to form the input signal, and wherein the input signal adjustment circuit is further configured to adjust the input voltage by an adjustment of a gain of the pre-amplifier.

Clause 6. The transmitter of clause 5, further comprising:
a modem processor configured to digitally pre-distort a digital signal to provide a digital baseband signal;
a digital-to-analog converter configured to convert the digital baseband signal into an analog baseband signal; and
an upconverter configured to upconvert the analog baseband signal to form the radio frequency signal.

Clause 7. The transmitter of clause 6, wherein the modem processor is further configured to digitally pre-distort the digital signal with a fixed amount of digital pre-distortion.

Clause 8. The transmitter of clause 2, wherein the look-up table is based upon a plurality of reference amplitude-modulation-to-amplitude-modulation curves for the envelope-tracking amplifier.

Clause 9. The transmitter of any of clauses 1-8, wherein the envelope-tracking amplifier comprises an envelope-tracking power amplifier in a cellular telephone.

Clause 10. A method of maintaining an amplifier compression, comprising:
forming an envelope-tracking power supply voltage based upon an envelope of an input signal;
amplifying the input signal in an amplifier powered by an envelope-tracking power supply voltage to form an output signal;
mapping the envelope-tracking power supply voltage into an input voltage scaling factor and into an output voltage scaling factor;
multiplying a voltage of the input signal by the input voltage scaling factor to form a scaled input voltage;
multiplying a voltage of the output voltage by the output voltage scaling factor to form a scaled output voltage;
determining a current compression of the amplifier responsive to a function of the scaled output voltage and the scaled input voltage; and
adjusting the input signal to maintain a fixed amount of compression for the amplifier based upon a difference between the current compression and fixed amount of compression.

Clause 11. The method of clause 10, wherein adjusting the input signal comprises adjusting a power level of the input signal.

Clause 12. The method of clause 11, wherein adjusting the power level comprises increasing the power level in response to the current compression being less than the fixed amount of compression.

Clause 13. The method of clause 11, wherein adjusting the power level comprises decreasing the power level in response to the current compression being greater than the fixed amount of compression.

Clause 14. The method of any of clauses 10-13, further comprising:
digitally pre-distorting the input signal to address a non-linearity in the output signal from the fixed amount of compression.

Clause 15. A transmitter, comprising:
an envelope-tracking amplifier;
means for calculating a compression for the envelope-tracking amplifier from a power supply voltage to the envelope-tracking amplifier, an input signal voltage to the envelope-tracking amplifier, and output signal voltage from the envelope-tracking amplifier; and
means for adjusting the input signal voltage to the envelope-tracking amplifier based upon a difference between the compression and a desired fixed value for the compression.

Clause 16. The transmitter of clause 15, wherein the transmitter further comprises:
a modem processor configured to digitally pre-distort a digital signal to provide a digital baseband signal;
a digital-to-analog converter configured to convert the digital baseband signal into an analog baseband signal; and
an upconverter configured to upconvert the analog baseband signal in frequency to form an upconverted signal, wherein an input signal to envelope-tracking amplifier is derived from the upconverted signal.

Clause 17. The transmitter of clause 16, wherein the modem processor is further configured to apply a fixed amount of digital pre-distortion to the digital signal to provide the digital baseband signal.

Clause 18. The transmitter of clause 16, further comprising:
a pre-amplifier configured to amplify the upconverted signal to form the input signal, and wherein the means for adjusting the input signal voltage is further configured to adjust the input signal voltage through an adjustment of a gain of the pre-amplifier.

Clause 19. The transmitter of clause 16, further comprising:
an envelope detector configured to detect an envelope of the digital baseband signal; and
an envelope amplifier configured to amplify the envelope to provide the power supply voltage to the envelope-tracking amplifier.

Clause 20. The transmitter of any of clauses 15-19, wherein the envelope-tracking amplifier comprises an envelope-tracking power amplifier in a cellular telephone.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A transmitter, comprising:
an envelope-tracking amplifier configured to amplify an input signal having an input voltage into an output signal having an output voltage; and
an input signal adjustment circuit configured to adjust the input voltage responsive to a current power supply voltage to the envelope-tracking amplifier, the input voltage, and the output voltage to maintain a fixed amount of compression for the envelope-tracking amplifier.

2. The transmitter of claim 1, wherein the input signal adjustment circuit includes a look-up table for providing an input voltage scaling factor and an output voltage scaling factor responsive to the current power supply voltage.

3. The transmitter of claim 2, wherein the input signal adjustment circuit further includes a first multiplier for multiplying the input voltage with the input voltage scaling factor to provide a scaled input voltage and includes a second multiplexer for multiplying the output voltage with the output voltage scaling factor to provide a scaled output voltage, and wherein the input signal adjustment circuit is further configured to map the scaled input voltage and the scaled output voltage to determine a current compression for the envelope-tracking amplifier.

4. The transmitter of claim 3, wherein the input signal adjustment circuit is further configured to map the scaled input voltage and the scaled output voltage into a current gain for the envelope-tracking amplifier, and to determine the current compression as a difference between a maximum gain for the envelope-tracking amplifier and the current gain.

5. The transmitter of claim 1, further comprising:
a pre-amplifier configured to amplify a radio frequency signal to form the input signal, and wherein the input signal adjustment circuit is further configured to adjust the input voltage by an adjustment of a gain of the pre-amplifier.

6. The transmitter of claim 5, further comprising:
a modem processor configured to digitally pre-distort a digital signal to provide a digital baseband signal;
a digital-to-analog converter configured to convert the digital baseband signal into an analog baseband signal; and
an upconverter configured to upconvert the analog baseband signal to form the radio frequency signal.

7. The transmitter of claim 6, wherein the modem processor is further configured to digitally pre-distort the digital signal with a fixed amount of digital pre-distortion.

8. The transmitter of claim 2, wherein the look-up table is based upon a plurality of reference amplitude-modulation-to-amplitude-modulation curves for the envelope-tracking amplifier.

9. The transmitter of claim 1, wherein the envelope-tracking amplifier comprises an envelope-tracking power amplifier in a cellular telephone.

10. A method of maintaining an amplifier compression, comprising:
forming an envelope-tracking power supply voltage based upon an envelope of an input signal;
amplifying the input signal in an amplifier powered by an envelope-tracking power supply voltage to form an output signal;
mapping the envelope-tracking power supply voltage into an input voltage scaling factor and into an output voltage scaling factor;
multiplying a voltage of the input signal by the input voltage scaling factor to form a scaled input voltage;
multiplying a voltage of the output voltage by the output voltage scaling factor to form a scaled output voltage;
determining a current compression of the amplifier responsive to a function of the scaled output voltage and the scaled input voltage; and
adjusting the input signal to maintain a fixed amount of compression for the amplifier based upon a difference between the current compression and fixed amount of compression.

11. The method of claim 10, wherein adjusting the input signal comprises adjusting a power level of the input signal.

12. The method of claim 11, wherein adjusting the power level comprises increasing the power level in response to the current compression being less than the fixed amount of compression.

13. The method of claim 11, wherein adjusting the power level comprises decreasing the power level in response to the current compression being greater than the fixed amount of compression.

14. The method of claim 10, further comprising:
digitally pre-distorting the input signal to address a non-linearity in the output signal from the fixed amount of compression.

15. A transmitter, comprising:
an envelope-tracking amplifier;
means for calculating a compression for the envelope-tracking amplifier from a power supply voltage to the envelope-tracking amplifier, an input signal voltage to the envelope-tracking amplifier, and output signal voltage from the envelope-tracking amplifier; and
means for adjusting the input signal voltage to the envelope-tracking amplifier based upon a difference between the compression and a desired fixed value for the compression.

16. The transmitter of claim 15, wherein the transmitter further comprises:
a modem processor configured to digitally pre-distort a digital signal to provide a digital baseband signal;
a digital-to-analog converter configured to convert the digital baseband signal into an analog baseband signal; and
an upconverter configured to upconvert the analog baseband signal in frequency to form an upconverted signal, wherein an input signal to envelope-tracking amplifier is derived from the upconverted signal.

17. The transmitter of claim 16, wherein the modem processor is further configured to apply a fixed amount of digital pre-distortion to the digital signal to provide the digital baseband signal.

18. The transmitter of claim 16, further comprising:
a pre-amplifier configured to amplify the upconverted signal to form the input signal, and wherein the means for adjusting the input signal voltage is further configured to adjust the input signal voltage through an adjustment of a gain of the pre-amplifier.

19. The transmitter of claim 16, further comprising:
an envelope detector configured to detect an envelope of the digital baseband signal; and
an envelope amplifier configured to amplify the envelope to provide the power supply voltage to the envelope-tracking amplifier.

20. The transmitter of claim 15, wherein the envelope-tracking amplifier comprises an envelope-tracking power amplifier in a cellular telephone.
